(19) United States
(12) Patent Application Publication
(10) Pub. No.: US 2020/0251677 A1
(43) Pub. Date: Aug. 6, 2020

(54) HEAT DISSIPATION FILM AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Yijia WANG, Wuhan, Hubei (CN); Jun CAO, Wuhan, Hubei (CN); Jiajia SUN, Wuhan, Hubei (CN)

(21) Appl. No.: 16/484,525

(22) PCT Filed: Apr. 24, 2019
(86) PCT No.: PCT/CN2019/083990

§ 371 Date: Aug. 8, 2019

(30) Foreign Application Priority Data
Jan. 31, 2019 (CN) 201910096619.X

(51) Int. Cl. H01L 51/52

(52) U.S. Cl. CPC H01L 51/529; H01L 51/5293; H01L 51/5253

(57) ABSTRACT

A heat dissipating film for a display panel includes a substrate, a plurality of thermally conductive studs each having one end perpendicularly connected to the substrate, and a filling layer filled in a mixed layer. The heat dissipating film and the display panel directly construct a three-in-one structure of “filled layer/longitudinal thermally conductive structure material/substrate.”

### FIELD OF INVENTION

The present disclosure relates to the field of display, and in particular to a heat dissipation film and a display panel.

### BACKGROUND OF INVENTION

Flexible organic light emitting diode (OLED) displays are emerging develop trends in display industry because flexible OLED displays possess features of low power consumption, high resolution, fast response times, bendability, etc. The thinner the thickness, the greater the market competitiveness. At present, a flexible material such as polyimide (PI) or polyethylene terephthalate (PET) is often used as a substrate. A thin film transistor (TFT), an OLED, and a thin film encapsulation (TFE) are sequentially disposed on the substrate. Then, a polarizer and a cover window are bound on an upper side thereof. In order to drive the TFT, it is necessary to bond an IC circuit at a bottom of the flexible substrate, thereby forming a panel. When the display is operating, heat is generated when current is passing through the TFT circuit. In order to facilitate heat dissipation, a foam/graphite/copper foil three-in-one structure is often added to a back of the PI by a laminating process. The foam/graphite/copper foil three-in-one structure includes foam that is made of acrylic material, graphite, and Cu coil. However, the three-in-one structure has a large thickness and the graphite is a sheet structure. The heat is mainly conducted along a direction of the sheet, so the heat dissipation effect of the display panel is less than desirable.

As shown in FIG. 1, which discloses a high thermal conductive metal foil layer/graphene metal mixed layer composite heat dissipating film. Graphene and metal particles are used and mixed to manufacture a slurry which serves as a thermally conductive stud. However, this particle coating method cannot ensure a thermal contact continuously forms between the particles and a lower layer. The internal heat conduction network is incomplete, an effect of heat transfer is poor in a vertical direction, and the manufacturing method thereof contains defects.

### Technical Problems

An object of the present disclosure is to provide a heat dissipating film and a display panel, which solve the problems of poor heat dissipation effect and large thickness of heat dissipating film in the prior art.

### SUMMARY OF INVENTION

The present disclosure provides a heat dissipating film, comprising:

a substrate;

a mixed layer comprising a plurality of thermally conductive studs, wherein one end of each of the thermally conductive studs is perpendicularly connected to the substrate; and

a filling layer filled in the mixed layer.

Furthermore, material of the thermally conductive studs comprises one of carbon nanotubes, carbon fibers, metal nanopillars, and oxide nanorods.

Furthermore, the substrate is a copper foil or an aluminum foil.

Furthermore, a thickness of the substrate is 1 μm to 50 μm.

Furthermore, the thermally conductive studs are cylindrical solid tube structures.

Furthermore, the thermally conductive studs are cylindrical hollow tube structures.

Furthermore, the filling layer comprises one of polyurethane, polystyrene, polyvinyl chloride, and polyethylene.

The present disclosure further provides a display panel, comprising the heat dissipation film, wherein the display panel further comprises a backplate, the heat dissipation film is disposed on the backplate, and wherein the substrate is disposed away from the backplate.

Furthermore, the display panel further comprises: a flexible substrate attached to a side of the backplate which is away from the heat dissipation film; a thin film transistor attached to a side of the flexible substrate which is away from the backplate; a thin film encapsulation layer disposed on a side of the thin film transistor which is away from the flexible substrate; a light emitting layer disposed between the thin film encapsulation layer and the thin film transistor, wherein the thin film encapsulation layer completely covers the light emitting layer;

a touch layer disposed on a side of the thin film encapsulation layer which is away from the thin film transistor; a polarizer disposed on the touch layer; and a cover plate disposed on the polarizer.

Furthermore, the display panel further comprises optical adhesives disposed between the cover plate and the polarizer, and disposed between the thin film encapsulation layer and the touch layer.

### Beneficial Effects

The heat dissipating film and the display panel directly construct a three-in-one structure of “filled layer/longitudinal thermally conductive structure material/substrate”, so that heat dissipation effect is enhanced and heat generated by the display panel is directly transferred to the substrate along a longitudinal direction of the thermally conductive material, thereby greatly shortening a heat conduction path. Meanwhile, the thermal conductive studs are directly deposited on the substrate and a filling layer is added, so as to reduce an overall thickness of the three-in-one composite structure.

### DESCRIPTION OF DRAWINGS

In order to illustrate technical solutions in the embodiments of the present disclosure more clearly, the accompanying drawings required in the description of the embodiments are introduced briefly hereafter. It is obvious that the accompanying drawings in the following description are merely part of the embodiments of the present disclosure. People with ordinary skills in the art can obtain other drawings without making inventive efforts.

FIG. 1 is a schematic view of a composite heat dissipation film in the prior art.

FIG. 2 is a schematic view of a heat dissipation film of a first embodiment.

FIG. 3 is a schematic view of a heat dissipation film of a second embodiment.

FIG. 4 is a schematic view of a display panel of the first embodiment.

FIG. 5 is a schematic view of a display panel of the second embodiment.

FIG. 6 is a top view of the heat dissipation film of the first embodiment.

FIG. 7 is a top view of another heat dissipation film of the first embodiment.

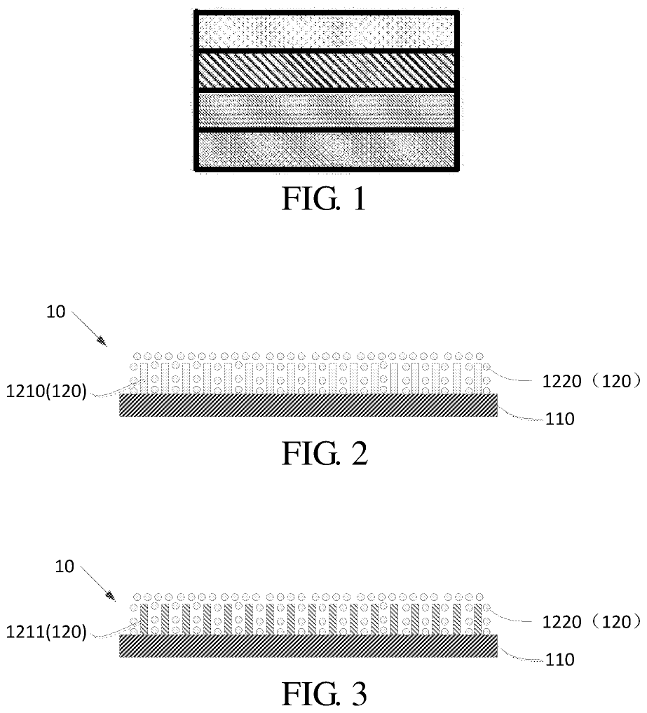

### REFERENCE NUMERALS IN DRAWINGS

100 flexible display panel;
10 heat dissipation film;
110 substrate; 120 mixed layer;
1210 first thermally conductive stud; 1211 second thermally conductive
stud; 1220 filling layer;
20 flexible substrate; 210 backplate; 220 flexible substrate;
230 thin film transistor; 240 light emitting layer; 250 thin film
encapsulation layer;
260 optical adhesive; 270 touch layer; 280 polarizer; and
290 cover plate;

### DETAILED DESCRIPTION OF PREFERRED EMBODIMENTS

The technical solutions of the embodiments of the present disclosure will be illustrated completely and clearly in combination with the following drawings of the embodiments of the disclosure. Apparently, the described embodiments are merely a few rather than all of the embodiments of the present disclosure. All other embodiments obtained by persons of ordinary skill in the art based on the embodiment of the present disclosure without creative efforts shall fall within the protection scope of the present disclosure.

In the specification, claims, and accompanying drawings of the present disclosure, the terms “first”, “second”, “third”, “fourth”, and so on (if exist), are intended to distinguish between similar objects but do not necessarily indicate specific order or a specific sequence. It should be understood that the data termed in such a way are interchangeable in proper circumstances so that the embodiments of the present disclosure described herein can be implemented in order except the order illustrated or described herein. Moreover, the terms “include”, “contain” and any other variants mean to cover the non-exclusive inclusion.

The accompanying drawings discussed below, and the various embodiments used to describe the principles of the present disclosure in this patent document are by way of illustration only and should not be construed in any way to limit the scope of the present disclosure. Those skilled in the art will understand that the principles of the present invention may be implemented in any suitably arranged system. The exemplary embodiments will be described in detail and examples of these embodiments are illustrated in the accompanying drawings. In addition, a terminal according to the exemplary embodiments will be described in detail with reference to the accompanying drawings. The same reference numerals in the drawings denote the same elements.

The terms used in the present specification are merely used to describe particular embodiments, and are not intended to limit the inventive concept. An expression used in the singular form encompasses the expression in the plural form, unless it has a clearly different meaning in the context. In the present specification, it is to be understood that the terms such as “comprising” “having,” and “including” are intended to indicate the existence of the features, numbers, steps, actions, components, parts, or combinations thereof disclosed in the specification, and are not intended to preclude the possibility that one or more other features, numbers, steps, actions, components, parts, or combinations thereof can exist or can be added. The same reference numerals in the drawings denote the same elements.

Embodiments of the present disclosure provide a heat dissipation film and a display panel which will be separately described in detail below.

### The First Embodiment

As shown in FIG. 2, the heat dissipation film 10 of the present disclosure includes a substrate 110 and a mixed layer 120 according to the present embodiment.

The substrate 110 is a copper foil substrate or an aluminum foil substrate, preferably a copper foil substrate.

The mixed layer 120 includes a first thermally conductive stud 1210 and a filling layer 1220.

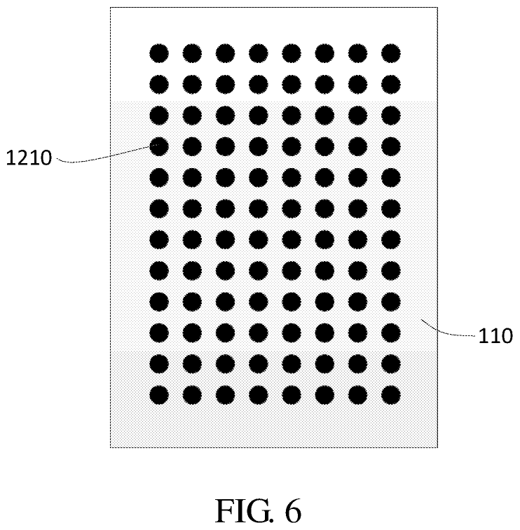

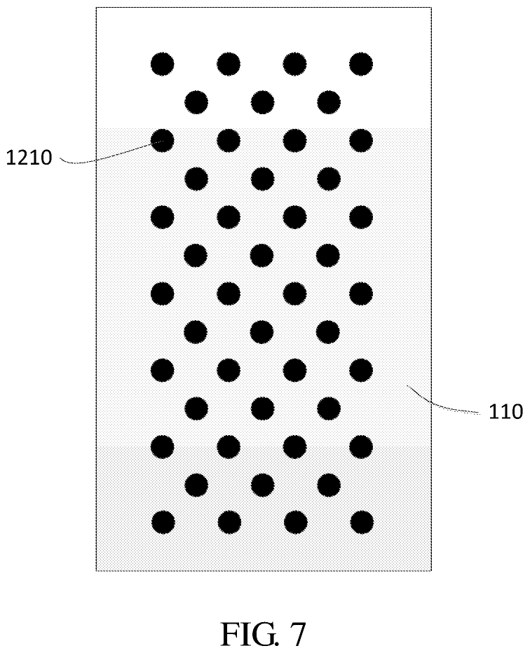

The first thermally conductive stud 1210 is a one-dimensional longitudinal structure and material of the first thermally conductive stud 1210 includes, but is not limited to, one of carbon nanotubes, carbon fibers, metal nanometers, and oxide nanometers. In the present embodiment, the first thermally conductive stud 1210 is a longitudinally arranged hollow cylindrical structure which produces a heat transfer effect in a vertical direction and shortens a heat conduction path. As shown in FIG. 6, projections of the first thermally conductive studs 1210 on the substrate 110 are circular shapes having equal intervals. The intervals can be adjusted to achieve an optimal heat dissipation effect. As shown in FIG. 7, the projections of the first thermally conductive studs 1210 on the substrate 110 are circular shapes spaced apart from each other according to another embodiment of the present disclosure. The spacing of the first thermally conductive studs 1210 can be adjusted to achieve an optimal heat dissipation. effect.

In order to reduce stress of the first thermally conductive studs 1210 in the vertical direction, a buffering agent, i.e., the filling layer 1220, is filled in a gap of the first thermally conductive studs 1210. The filling layer 1220 is an elastic polymer which has a good elasticity and flexibility and is functional for buffering the stress of the longitudinal first thermally conductive studs 1210, while reducing an area and a thickness of the filling layer 1220 and reducing a thickness of the heat dissipating film 10. The improved thickness of the heat dissipating film 10 is about 50 μm to 150 μm.

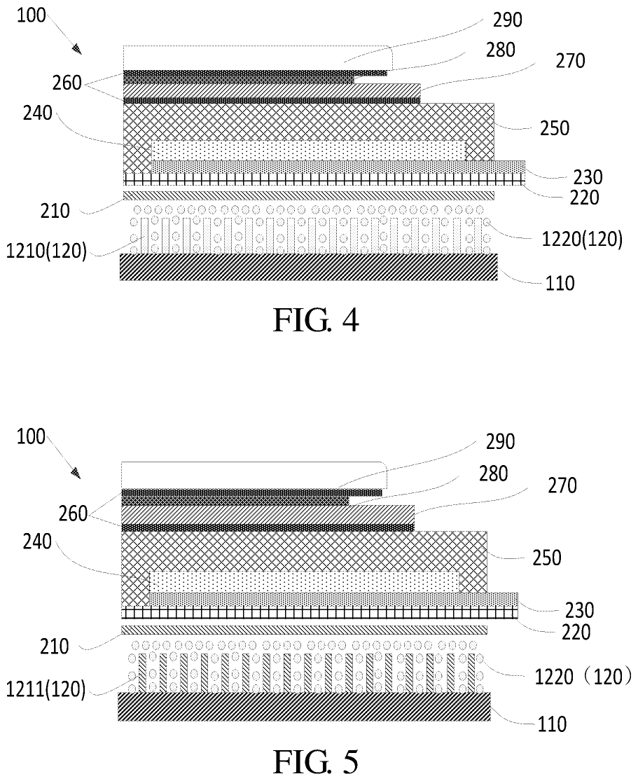

As shown in FIG. 4, in the embodiment, the present disclosure further provides a flexible display panel 100, including the heat dissipation film 10 of the present embodiment. The flexible display panel 100 further includes a flexible substrate 20. The flexible substrate includes a backplate 210, a flexible base plate 220, a thin film transistor 230, a light-emitting layer 240, a thin film encapsulation layer 250, an optical adhesive 260, a touch layer 270, a polarizer 280, and a cover plate 290.

The heat dissipation film 10 is disposed on the backplate 210. The substrate 110 is disposed away from the backplate 210.

The flexible substrate 20 is attached to a side of the backplate 110 away from the heat dissipation film 10. The thin film transistor 230 is attached to a side of the flexible substrate 20 away from the backplate 210.

The thin film encapsulation layer 230 is disposed on a side of the thin film transistor 230 away from the flexible substrate 20.

The light emitting layer 240 is disposed between the thin film encapsulation layer 250 and the thin film transistor 230. The thin film encapsulation layer 250 completely covers the light emitting layer 240.

The touch layer 270 is disposed on a side of the thin film encapsulation layer 250 away from the thin film transistor 230.

A side of the polarizer 280 is located on the touch layer 270 and the other side of the polarizer 280 is located on the cover plate 290.

The optical adhesive 260 bonds the cover plate 290 and the polarizer 280, and bonds the thin film encapsulation layer 250 and the touch layer 270.

### The Second Embodiment

As shown in FIG. 3, the heat dissipation film 10 of the present disclosure includes a substrate 110 and a mixed layer 120 according to the present embodiment.

The substrate 110 is a copper foil substrate or an aluminum foil substrate, preferably a copper foil substrate.

The mixed layer 120 includes a plurality of second thermally conductive studs 1211 and a filling layer 1220.

Each of the second thermally conductive studs 1211 is one-dimensional longitudinal structure and material of the second thermally conductive studs 1211 is one of carbon nanotubes, carbon fibers, metal nanometers, and oxide nanometers. In the present embodiment, the second thermally conductive stud 1211 is a longitudinally arranged solid cylindrical structure which produces a heat transfer effect in a vertical direction and shortens a heat conduction path. In order to reduce stress of the second thermally conductive studs 1211 in the vertical direction, a buffering agent, i.e., the filling layer 1220, is filled in a gap of the second thermally conductive studs 1211. The filling layer 1220 is an elastic polymer which has a good elasticity and flexibility and is functional for buffering the stress of the longitudinal second thermally conductive studs 1211, while reducing an area and a thickness of the filling layer 1220 and reducing a thickness of the heat dissipating film 10. The improved thickness of the heat dissipating film 10 is about 50 μm to 150 μm.

As shown in FIG. 5, in the present embodiment, the present disclosure further provides a flexible display panel 100, including the heat dissipation film 10 of the present embodiment. The flexible display panel 100 further includes a flexible substrate 20. The flexible substrate includes a backplate 210, a flexible base plate 220, a thin film transistor 230, a light-emitting layer 240, a thin film encapsulation layer 250, an optical adhesive 260, a touch layer 270, a polarizer 280, and a cover plate 290.

The heat dissipation film 10 is disposed on the backplate 210. The substrate 110 is disposed away from the backplate 210.

The flexible substrate 20 is attached to a side of the backplate 110 away from the heat dissipation film 10. The thin film transistor 230 is attached to a side of the flexible substrate 20 away from the backplate 210.

The thin film encapsulation layer 230 is disposed on a side of the thin film transistor 230 away from the flexible substrate 20.

The light emitting layer 240 is disposed between the thin film encapsulation layer 250 and the thin film transistor 230. The thin film encapsulation layer 250 completely covers the light emitting layer 240.

The touch layer 270 is disposed on a side of the thin film encapsulation layer 250 away from the thin film transistor 230.

A side of the polarizer 280 is located on the touch layer 270 and the other side of the polarizer 280 is located on the cover plate 290.

The optical adhesive 260 bonds the cover plate 290 and the polarizer 280, and bonds the thin film encapsulation layer 250 and the touch layer 270.

The preferred embodiments of the present disclosure are mentioned above, which cannot be used to limit the present disclosure. Any modifications or equivalent substitutions, and improvements made within spirit and principles of the present disclosure are considered encompassed in the scope of protection defined by the clams of the present disclosure.

1. A heat dissipation film, comprising:
a substrate;
a mixed layer comprising a plurality of thermally conductive studs, wherein one end of each of the thermally conductive studs is perpendicularly connected to the substrate; and
a filling layer filled in the mixed layer.

2. The heat dissipation film of claim 1, wherein material of the thermally conductive studs comprises one of carbon nanotubes, carbon fibers, metal nanopillars, and oxide nanorods.

3. The heat dissipation film of claim 1, wherein the substrate is a copper foil or an aluminum foil.

4. The heat dissipation film of claim 1, wherein a thickness of the substrate is 1 μm to 50 μm.

5. The heat dissipation film of claim 1, wherein the thermally conductive studs are cylindrical solid tube structures.

6. The heat dissipation film of claim 1, wherein the thermally conductive studs are cylindrical hollow tube structures.

7. The heat dissipation film of claim 1, wherein the filling layer comprises one of polyurethane, polystyrene, polyvinyl chloride, and polyethylene.

8. A display panel, comprising the heat dissipation film of claim 1, wherein the display panel further comprises a backplate, the heat dissipation film is disposed on the backplate, and wherein the substrate is disposed at a side of the display panel away from the backplate.

9. The display panel of claim 8, wherein the display panel further comprises:
a flexible substrate attached to a side of the backplate which is away from the heat dissipation film;
a thin film transistor attached to a side of the flexible substrate which is away from the backplate;
a thin film encapsulation layer disposed on a side of the thin film transistor which is away from the flexible substrate;
a light emitting layer disposed between the thin film encapsulation layer and the thin film transistor, wherein the thin film encapsulation layer completely covers the light emitting layer;
a touch layer disposed on a side of the thin film encapsulation layer which is away from the thin film transistor;
a polarizer disposed on the touch layer; and
a cover plate disposed on the polarizer.

10. The display panel of claim 9, wherein the display panel further comprises optical adhesives disposed between the cover plate and the polarizer, and disposed between the thin film encapsulation layer and the touch layer.
